(19) United States
(12) Patent Application Publication
(10) Pub. No.: US 2026/0193778 A1
(43) Pub. Date: Jul. 9, 2026

(54) VAPOR SUPPLY FOR SUBSTRATE PROCESSING SYSTEMS

(71) Applicant: LAM RESEARCH CORPORATION, Fremont, CA (US)

(72) Inventors: Curtis W. BAILEY, West Linn, OR (US); Rigel Martin BRUENING, Sherwood, OR (US); Jorge REYES, Tigard, OR (US); Ashwin KUMAR, Bangalore (IN); Kevin GERBER, Portland, OR (US); Mohammadreza BABAEI, Tigard, OR (US); Avinash JAISWAL, Bangalore (IN); Kyle Starr ODUM, Tigard, OR (US); Jiuyuan NIE, Beaverton, OR (US)

(21) Appl. No.: 19/131,857

(22) PCT Filed: Sep. 7, 2023
(86) PCT No.: PCT/US2023/032136

§ 371 Date: May 21, 2025

Related U.S. Application Data
(60) Provisional application No. 63/429,103, filed on Nov. 30, 2022.

(51) Int. Cl. C23C 16/455; C23C 16/44; C23C 16/448; C23C 16/52

(52) U.S. Cl. CPC C23C 16/45512; C23C 16/4408; C23C 16/4485; C23C 16/52

(57) ABSTRACT

A vapor supply system to supply vapor to a process module of a substrate processing tool includes an evaporator assembly to vaporize liquid and to supply the vaporized liquid as vapor to the process module. The evaporator assembly is located external to the substrate processing tool. The vapor supply system includes a gas box to receive the vapor supplied by the evaporator assembly and supply the vapor from the gas box to the process module. The gas box encloses a plurality of valves and respective mass flow controllers to selectively supply the vapor from the evaporator assembly and at least one process gas from a gas source to the process module. The gas box is mounted on or within the substrate processing tool.

### CROSS-REFERENCE TO RELATED APPLICATIONS

This application claims the benefit of U.S. Provisional Application No. 63/429,103 filed on Nov. 30, 2022. The entire disclosure of the above application is incorporated herein by reference.

### FIELD

The present disclosure relates to gas delivery systems for substrate processing systems, and more particularly to vapor supply for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems for performing deposition and/or etching typically include a processing chamber with a pedestal. A substrate such as a semiconductor wafer may be arranged on the pedestal during processing. A process gas mixture including one or more precursors may be introduced into the processing chamber to deposit film on the substrate or to etch the substrate. In some substrate processing systems, radio frequency (RF) plasma can be struck in the processing chamber and/or an RF bias on the pedestal may be used to activate chemical reactions.

Various gas flow paths in the gas delivery system are used to deliver process gases, carrier gases, oxidizing gases, precursor gases and/or purge gases to the processing chamber. The gas flow paths are defined by via tubing, valves, manifolds and gas flow channels in a valve inlet block. In some examples, one or more liquids are vaporized and supplied to the processing chamber as vapor.

### SUMMARY

A vapor supply system to supply vapor to a process module of a substrate processing tool includes an evaporator assembly to vaporize a liquid and to supply the vaporized liquid as vapor to the process module. The evaporator assembly is located external to the substrate processing tool. The vapor supply system includes a gas box to receive the vapor supplied by the evaporator assembly and supply the vapor from the gas box to the process module. The gas box encloses a plurality of valves and respective mass flow controllers to selectively supply the vapor from the evaporator assembly and at least one process gas from a gas source to the process module. The gas box is mounted on or within the substrate processing tool.

In other features, the evaporator assembly is located in a facilities supply cabinet external to the substrate processing tool. The evaporator assembly is located below a floor of a facility containing the substrate processing tool. The vapor supply system further includes a bulk liquid source to supply the liquid to the evaporator assembly. The vapor supply system further includes a first valve connected between the evaporator assembly and the gas box. The first valve selectively supplies the vapor from the evaporator assembly to the gas box. The first valve is located in the gas box. The vapor supply system further includes a filter connected between the gas box and the process module to filter contaminants from the vapor supplied to the process module. The vapor supply system further includes a second valve located within the gas box. The second valve selectively diverts the vapor from the gas box to a vacuum divert path.

In other features, the vapor supply system further includes an exterior disconnect panel of the substrate processing tool. A vapor supply line from the evaporator assembly is removably connected to the substrate processing tool at the exterior disconnect panel. The vapor supply system further includes a vapor supply interface including a disconnect panel disposed within the substrate processing tool between the vapor supply assembly and the gas box. The vapor is maintained in vapor from for an entirety of a supply path from the evaporator assembly to the process module. The vapor supply system further includes a heater to heat supply lines that supply the vapor from the evaporator assembly to the gas box. The evaporator assembly supplies vaporized alkylsilane to the gas box. The vaporized alkylsilane is vaporized tetramethylsilane. The vapor supply system further includes a bulk liquid source to supply the liquid to the evaporator assembly. The bulk liquid source contains liquid alkylsilane. The liquid alkylsilane is liquid tetramethylsilane.

A substrate processing system includes a substrate processing tool that includes a plurality of process modules each to process semiconductor substrates and a gas box to selectively supply gases to respective ones of the plurality of process modules, receive, from a remote location external to the substrate processing tool, vaporized alkylsilane, and supply, independently of the gases, the vaporized alkylsilane to a first process module of the plurality of process modules. The substrate processing system further includes an evaporator assembly external to the substrate processing tool to store or receive liquid alkylsilane, vaporize the liquid alkylsilane to form the vaporized alkylsilane, and supply the liquid alkylsilane from the remote location external to the substrate processing tool to the gas box.

In other features, the liquid alkylsilane is liquid tetramethylsilane and the vaporized alkylsilane is vaporized tetramethylsilane. The evaporator assembly is located in a facilities supply cabinet. The substrate processing system further includes a bulk liquid source to supply the liquid to the evaporator assembly. The vaporized alkylsilane is maintained in vapor form for an entirety of a supply path from the evaporator assembly external to the substrate processing tool to the first process module. Supply lines in at least a portion of the supply path are heated.

A substrate processing tool includes a plurality of process modules each to process semiconductor substrates and a gas box to selectively supply gases to respective ones of the plurality of process modules, receive, from an evaporator assembly in a remote location external to the substrate processing tool, vaporized alkylsilane, and supply, independently of the gases, the vaporized alkylsilane to a first process module of the plurality of process modules. The substrate processing tool and the gas box receive the vaporized alkylsilane from the evaporator assembly external to the substrate processing tool in vapor form. In other features, the vaporized alkylsilane is vaporized tetramethylsilane.

A system for supplying vaporized precursors to a process module of a substrate processing tool comprises a first evaporator assembly, a second evaporator assembly, and a gas box. The first evaporator assembly is configured to vaporize a first liquid precursor and to supply a first vaporized precursor through a first conduit. The second evaporator assembly is configured to vaporize a second liquid precursor and to supply a second vaporized precursor through a second conduit. The gas box is configured to mix the first and second vaporized precursors, to supply a mixture of the first and second vaporized precursors to the process module, and to at least partially evacuate the mixture from the gas box after a process step is completed to prevent condensation of at least one of the first and second vaporized precursors in the gas box.

In other features, the gas box is further configured to establish a steady flow of the mixture of the first and second vaporized precursors before supplying the mixture to the process module. At least one of the first and second conduits is heated to supply the first and second vaporized precursors to the gas box in vapor form. The gas box is connected to an exhaust system to evacuate the mixture. The gas box is further configured to receive a gas from a gas source and to add the gas to at least one of the first and second vaporized precursors before mixing the first and second vaporized precursors.

In other features, the gas box comprises a first inlet valve, a second inlet valve, a first mass flow controller, a second mass flow controller, a first outlet valve, a second outlet valve, a first valve, a second valve, and a third valve. The first inlet valve is configured to receive the first vaporized precursor from the first evaporator assembly via the first conduit. The second inlet valve is configured to receive the second vaporized precursor from the second evaporator assembly via the second conduit. The first mass flow controller is connected to the first inlet valve to regulate flow of the first vaporized precursor. The second mass flow controller is connected to the second inlet valve to regulate flow of the second vaporized precursor. The first outlet valve is connected to the first mass flow controller. The second outlet valve is connected to the second mass flow controller. A first valve has an input connected to outputs of the first and second outlet valves and has an output connected to the second valve coupled to the process module. The third valve is connected between input of the first valve and the outputs of the first and second outlet valves.

In other features, the system further comprises a controller configured to, before supplying the mixture to the process module: close the first and second inlet valves, the first and second outlet valves, the first and second valves, and turn off the first and second mass flow controllers; open the third valve and the first and second outlet valves; open the first and second inlet valves o allow the first and second vaporized precursors to flow through the first and second conduits into the gas box; turn on the first and second mass flow controllers to allow flow of the mixture to reach a steady state; and after the flow of the mixture reaching the steady state, close the third valve and open the first and second valves to supply the mixture to the process module.

In other features, the controller is further configured to, after the process step is performed in the process module using the mixture: open the third valve; close the first and second inlet valves and the first and second valves, while keeping the first and second outlet valves open and the first and second mass flow controllers on, to evacuate the mixture from the gas box and to prevent condensation of at least one of the first and second vaporized precursors in the gas box; close the first and second inlet valves, the first and second outlet valves, the first and second valves; and turn off the first and second mass flow controllers.

In other features, the system further comprises a first heater coupled to the first conduit, a second heater coupled to the second conduit, and a controller configured to control the first and second heaters to heat the first and second conduits to first and second temperatures, respectively, to maintain the first and second vaporized precursors in the first and second conduits in vapor form.

In other features, the system further comprises a first heater coupled to the first evaporator assembly, a second heater coupled to the second evaporator assembly, and a controller configured to control the first and second heaters to heat the first and second liquid precursors to first and second temperatures, respectively, to vaporize the first and second liquid precursors into the first and second vaporized precursors. The first and second liquid precursors comprise molybdenum hexafluoride and tungsten hexafluoride, respectively. The first and second evaporator assemblies are located in a facilities supply cabinet external to the substrate processing tool and wherein the gas box is mounted on or within the substrate processing tool. The first and second evaporator assemblies are located below a floor of a facility containing the substrate processing tool and wherein the gas box is mounted on or within the substrate processing tool.

A system for supplying a vaporized precursor to a process module of a substrate processing tool comprises an evaporator assembly configured to vaporize a liquid precursor and to supply the vaporized precursor through a conduit, and a gas box configured to supply the vaporized precursor to the process module and to at least partially evacuate the vaporized precursor from the gas box after a process step is completed to prevent condensation of vaporized precursor in the gas box.

In other features, the gas box is further configured to establish a steady flow of the vaporized precursor before supplying the vaporized precursor to the process module. The conduit is heated to supply the vaporized precursor to the gas box in vapor form. The gas box is connected to an exhaust system to evacuate the vaporized precursor. The gas box is further configured to receive a gas from a gas source and to add the gas to the vaporized precursor.

In other features, the gas box comprises an inlet valve, a mass flow controller, an outlet valve, a first valve, a second valve, and a third valve. The inlet valve is configured to receive the vaporized precursor from the evaporator assembly via the conduit. The mass flow controller is connected to the inlet valve to regulate flow of the vaporized precursor. The outlet valve is connected to the mass flow controller. The first valve has an input connected to an output of the outlet valve and has an output connected to a second valve coupled to the process module. The third valve is connected between input of the first valve and the output of the outlet valve.

In other features, the system further comprises a controller configured to, before supplying the vaporized precursor to the process module: close the inlet and outlet valves, the first and second valves, and turn off the mass flow controller; open the third valve and the outlet valve; open the inlet valve to allow the vaporized precursor to flow through the conduit into the gas box; turn on the mass flow controller to allow flow of the vaporized precursor to reach a steady state; and after the flow of the vaporized precursor reaching the steady state, close the third valve and open the first and second valves to supply the vaporized precursor to the process module.

In other features, the controller is further configured to, after the process step is performed in the process module using the vaporized precursor: open the third valve; close the inlet valve and the first and second valves, while keeping the outlet valve open and the mass flow controller on, to evacuate the vaporized precursor from the gas box and to prevent condensation of the vaporized precursor in the gas box; and close the inlet and outlet valves and the first and second valves, and turn off the mass flow controller.

In other features, the system further comprises a heater coupled to the conduit, and a controller configured to control the heater to heat the conduit to maintain the vaporized precursor in the conduit in vapor form. The system further comprises a heater coupled to the evaporator assembly, and a controller configured to control the heater to heat the liquid precursor to vaporize the liquid precursor into the vaporized precursor.

In other features, the gas box further comprises a fourth valve connected to a source of an inert gas, the fourth valve being connected between the inlet valve and the mass flow controller to add the inert gas to the vaporized precursor. The liquid precursor comprises tetramethylsilane. The system further comprises a filter connected between the second valve and the process module to filter contaminants from the vaporized precursor supplied to the process module.

In other features, the evaporator assembly is located in a facilities supply cabinet external to the substrate processing tool and wherein the gas box is mounted on or within the substrate processing tool. The evaporator assembly is located below a floor of a facility containing the substrate processing tool and wherein the gas box is mounted on or within the substrate processing tool.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIGS. 2A and 2B are functional block diagrams of a vapor supply system and substrate processing tool according to the present disclosure;

FIG. 3 illustrates an example vapor pressure curve for a vaporized liquid supplied to a processing chamber according to the present disclosure;

FIG. 4 illustrates an example configuration of a vapor supply system and substrate processing tool according to the present disclosure; and

FIG. 5 is a flowchart of a method of supplying one or more vaporized precursors to a processing chamber according to the present disclosure.

In the drawings, reference numbers may be reused to identify similar and/or identical elements.

### DETAILED DESCRIPTION

A gas delivery system includes an arrangement of tubing, valves, manifolds, and gas flow channels to supply gas mixtures to respective processing chambers or stations of a substrate processing tool in a substrate processing system (e.g., a substrate processing system configured to perform deposition processes including, but not limited to, chemical vapor deposition (CVD), plasma enhanced CVD (PECVD), and thermal atomic layer deposition (ALD)). The gas delivery system may be further configured to supply vapor to the processing chambers. In some processes, the gas delivery system supplies a vaporized alkylsilane, such as vaporized tetramethylsilane (4MS).

In some examples, the gas delivery system includes a vaporizer and a liquid flow controller arranged to flow vaporized liquids (e.g., precursors) such as 4MS. Vaporizers may have a high response time (e.g., between 0.5 and 5.0 seconds to ramp up to full output). In other examples, ampoules are used to heat liquid to form vapor within a canister. A carrier gas may flow into the ampoule to entrain the vapor. Vapor is supplied from the ampoule to the processing chamber using a mass flow controller (MFC). When using a carrier gas, a mass flow meter (MFM) is used on the process module to measure total amount of vapor/gas mixture when the vapor/gas mixture reaches the process module.

Vapor supply systems and methods according to the present disclosure are configured to vaporize a liquid precursor in a remote location (i.e., remotely located from the substrate processing tool) and to supply the vaporized liquid to the substrate processing system from the remote location. In an example, the remote location corresponds to a facilities supply cabinet. In some examples, one or more components of the vapor supply system is located below a floor of a facility (e.g., below the substrate processing tool) containing the substate processing system.

For example, the liquid may be stored in bulk liquid source or container in the facilitates supply cabinet. The liquid is supplied to an evaporator assembly that is heated to convert the liquid to vapor. The vapor is supplied to the substrate processing tool as a result of a pressure difference between the evaporator assembly and a corresponding processing chamber. Supply of the vapor into the processing chamber may be controlled using a mass flow controller (e.g., a mass flow controller located within a gas box of the substrate processing tool).

Further, in some applications, two vaporized precursors (e.g., molybdenum hexafluoride MoF6 and tungsten hexafluoride WF6) may be supplied from respective vaporizer assemblies. The vaporized precursors may be combined in a gas box, and a mixture of the vaporized precursors may be supplied to the processing chamber. The vaporizer assemblies may be located in a facilitates supply cabinet remote from the substrate processing tool. For example, two vaporizer assemblies may be used to vaporize two liquid precursors (e.g., MoF6 and WF6), respectively. The vaporized precursors are then supplied from the respective vaporizer assemblies through separate heated conduits to the gas box located at or in the substrate processing tool. The vaporized precursors are combined in the gas box, and the mixture of the vaporized precursors is supplied to the processing chamber.

To prevent condensation of the vaporized precursors upstream from the processing chamber generally and particularly in the gas box, the conduits supplying the vaporized precursors from the vaporizer assemblies to the gas box are heated. Heating the conduits ensures that the vaporized precursors enter the gas box in vapor form and no condensation occurs in the supply conduits. Additionally, valves in the gas box used to supply the vaporized precursors to the processing chamber and to divert the vaporized precursors to a foreline (exhaust system) of the substrate processing tool are controlled. The valves between the vaporizer assemblies and the processing chamber are controlled so that before supplying the vaporized precursors to the processing chamber, the flow of the vaporized precursors reaches a steady state. After the vaporized precursors reach the steady state and a process step is performed in the processing chamber using the vaporized precursors, the valves are controlled to evacuate the vaporized precursors from the gas box (e.g., from conduits and valves upstream from the processing chamber and in the gas box) to prevent condensation of the vaporized precursors in the gas box and upstream from the processing chamber. These and other features of the present disclosure are described below in detail.

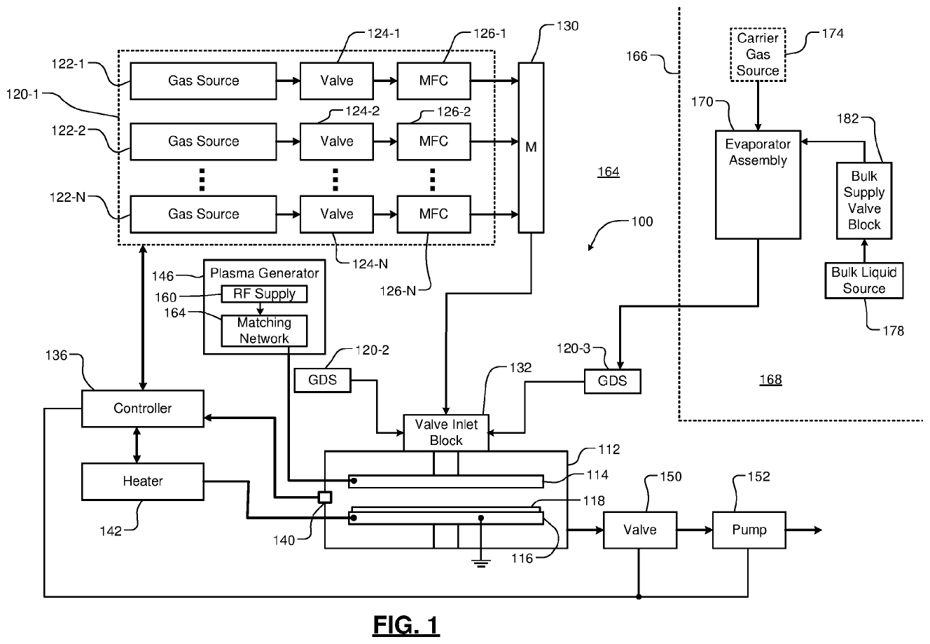

Referring now to FIG. 1, an example substrate processing system 100 includes a processing chamber 112 with a reaction volume. In some examples, the substrate processing system 100 is configured to perform a plasma-enhanced chemical vapor deposition (PECVD) or plasma enhanced atomic layer deposition (PEALD) process. Process gas mixtures may be supplied to the processing chamber 112 using a gas distribution device 114 such as a showerhead. In some examples, the showerhead is a chandelier-type showerhead. A substrate 118 such as a semiconductor wafer may be arranged on a substrate support 116 during processing. The substrate support 116 may include a pedestal, an electrostatic chuck, a mechanical chuck or other type of substrate support.

One or more gas delivery systems (GDS) 120-1, 120-2, and 120-3 may each include one or more gas sources 122-2, 122-2, . . . , and 122-N (collectively gas sources 122), where N is an integer greater than one. Valves 124-1, 124-2, . . . , and 124-N (collectively valves 124), mass flow controllers 126-1, 126-2, . . . , and 126-N (collectively mass flow controllers 126), or other flow control devices may be used to supply one or more gases to a manifold 130, which supplies a gas mixture through a valve inlet block 132 to the processing chamber 112. The valve inlet block 132 includes a plurality of valves and defines respective flow paths for gas mixtures supplied to the processing chamber 112. The valve inlet block 132 may include one or more divert paths for selectively diverting gas to vacuum or exhaust. One or more additional gas delivery systems may be provided to supply gases or gas mixtures in other locations.

A controller 136 may be used to monitor process parameters such as temperature, pressure, etc. (using one or more sensors 140) and to control process timing. The controller 136 may be used to control process devices such as gas delivery systems 120-1, 120-2 and 120-3, a substrate support heater 142, and/or an RF plasma generator 146. The controller 136 may also be used to evacuate the processing chamber 112 using a valve 150 and pump 152.

The RF plasma generator 146 generates the RF plasma in the processing chamber. The RF plasma generator 146 may be an inductive or capacitive-type RF plasma generator. In some examples, the RF plasma generator 146 may include an RF supply 160 and a matching and distribution network 162. While the RF plasma generator 146 is shown connected to the gas distribution device 114 and the substrate support is grounded or floating, the RF plasma generator 146 can be connected to the substrate support 116 and the gas distribution device 114 can be grounded or floating.

Generally, the substrate processing system 100 is implemented as a substrate processing tool that comprises one or more process modules, each of which may be implemented as the processing chamber 112. Although only one processing chamber 112 is shown, each process module may comprise multiple processing chambers or stations. Typically, various components are disposed in and/or on the substrate processing tool. These components are shown in FIG. 1 on a tool side 164 of a dashed line 166. Conversely, other components are shown on a facilities side 168 of the dashed line 166. The components on the facilities side 168 are located external to the substrate processing tool, such as in a facilities supply cabinet, below a subfloor, etc.

Components located on the facilities side 168 according to the present disclosure include an evaporator assembly 170. The evaporator assembly 170 is configured to supply vaporized precursor (e.g., 4MS vapor) to the processing chamber 112 (e.g., through a gas box of a GDS such as the GDS 120-3) as described below in more detail. In some examples, a carrier gas is supplied to the evaporator assembly 170 (e.g., to a canister via an evaporator valve block, not shown in FIG. 1) from a carrier gas source 174. Liquid (e.g., liquid 4MS) is supplied to the evaporator assembly 170 from a bulk liquid source 178 via a bulk supply valve block 182. In an embodiment, the evaporator assembly 170 and the bulk liquid source 178 are located in a facilities supply cabinet.

Accordingly, in the substrate processing system 100 according to the present disclosure and as described below in more detail, a liquid precursor is vaporized in a remote location and then supplied to the substrate processing chamber 112 as vapor from the remote location. As used herein, “remote location” refers to a location external to the substrate processing tool (e.g., not within a gas delivery system mounted on or adjacent to the substrate processing tool, in a gas box of the substrate processing tool, etc.).

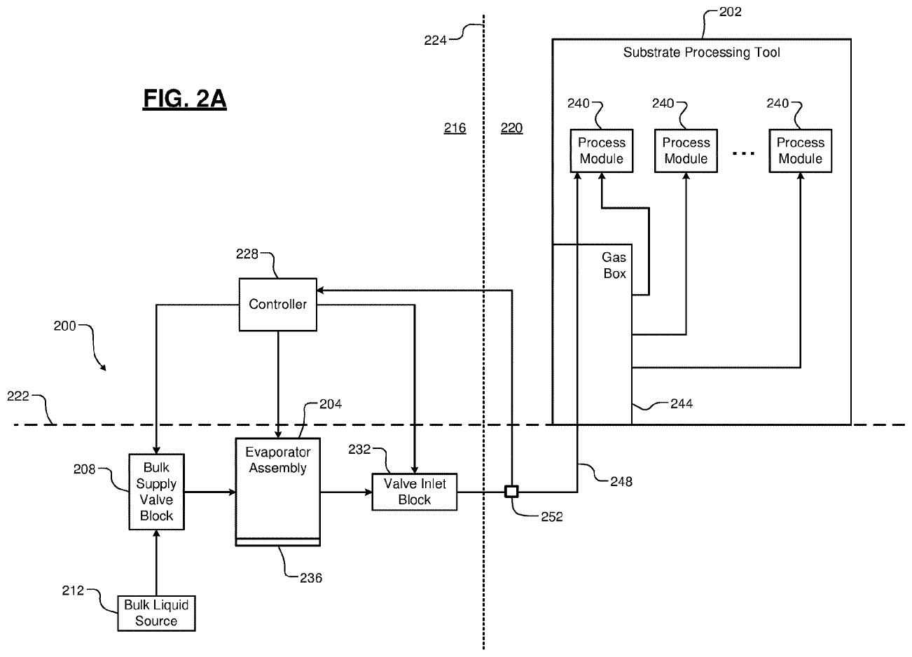

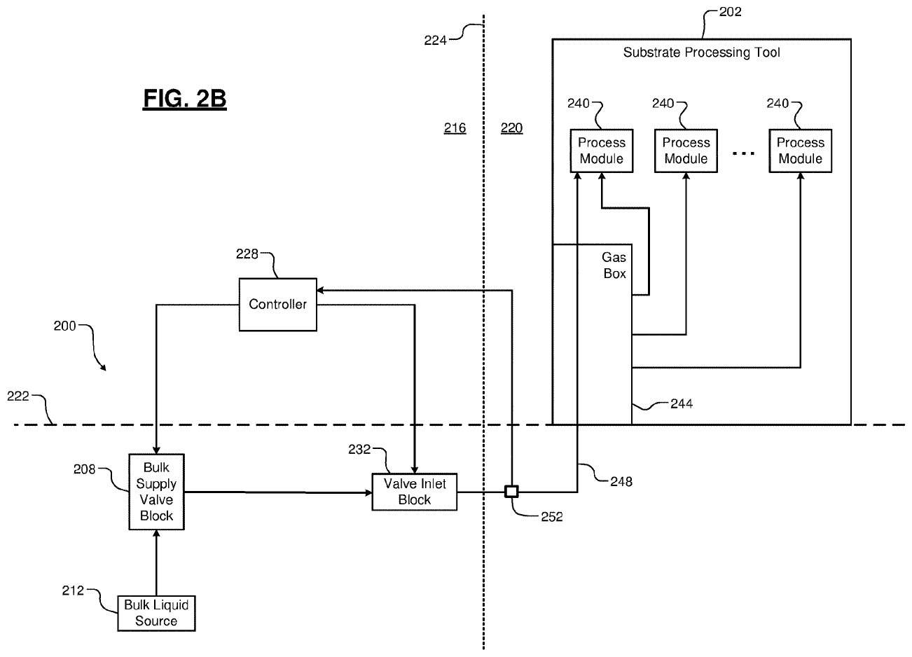

A vapor supply system 200 configured to supply vapor from a remote location to a substrate processing tool 202 according to the present disclosure is described in more detail in FIGS. 2A and 2B. As shown in FIG. 2A, the vapor supply system 200 includes an evaporator assembly 204 in fluid communication with a bulk supply valve block 208 configured to selectively supply liquid (e.g., a liquid precursor, such as 4MS) from a facility bulk liquid source 212 to the evaporator assembly 204. In this example, the evaporator assembly 204 is configured to vaporize the liquid. Although not shown, in some examples the vapor supply system 200 includes a carrier gas source configured to supply a carrier gas into the evaporator assembly 204 to entrain vapor.

Although shown in FIG. 2A as separate components, in some examples the evaporator assembly 204 and the bulk liquid source 212 may be implemented as a single component, such as an evaporator assembly including a bulk liquid source. For example, as shown in FIG. 2B, the bulk liquid source 212 itself is configured as an evaporator assembly to vaporize the liquid (e.g., using a wrap heater) and supply vapor to the substrate processing tool 202. In other words, in this example, a separate, external evaporator assembly such as the evaporator assembly 204 shown in FIG. 2A is omitted.

At least the evaporator assembly 204 and the bulk liquid source 212 are located external to the substrate processing tool 202, such as in facilities supply cabinet (e.g., beneath a floor of a facility). As shown in FIGS. 2A and 2B, components shown on a facilities side 216 of a dashed line 220 are located in a facilities supply cabinet, below a floor 222 of the facility, etc. In one example, the evaporator assembly 204 is located over 20 feet (e.g., 100 feet) from the substrate processing tool 202. Conversely, components shown on a tool side 224 of the dashed line 220 may be located on or in the substrate processing tool 202. In some examples, one or more components of the vapor supply system 200 (e.g., a controller 228, a valve inlet block 232, etc.) may be located on the tool side 224.

As shown in FIG. 2A, vapor is formed in the evaporator assembly 204 when the evaporator assembly 204 is heated (e.g., using a heater 236 responsive to control signals received from the controller 228). The heater 236 may correspond to one or more separately or collectively controlled resistive heaters, a jacket or wrap heater (e.g., a heater film or layer), etc. In some examples, the heater 236 may include one or more flanged insertion heaters extending through the bottom and/or sidewalls of the evaporator assembly 204 to directly heat the liquid.

The evaporator assembly 204 selectively supplies vapor to the valve inlet block 232. For example, to supply vapor, the heater 236 is controlled to heat the liquid inside the evaporator assembly 204 to form the vapor. Valves of the evaporator assembly 204 and the valve inlet block 232 are selectively controlled (e.g., using the controller 228) to flow the vapor out of the evaporator assembly 204, through the valve inlet block 232, and into the substrate processing tool 202. The controller 228 is further configured to controller the bulk supply valve block 208 to supply additional liquid to the evaporator assembly.

The substrate processing tool 202 includes one or more process modules 240. Each of the process modules 240 may correspond to a single or multi-station process module having one or more processing stations (e.g., corresponding to a processing chamber such as the processing chamber 112). The process modules 240 receive gases and gas mixtures (e.g., process gases, purge gases, etc.) via a gas box 244 of the substrate processing tool 202. Although only one gas box 244 is shown, the substrate processing tool 202 may include two or more gas boxes.

The gas box 244 houses components of a gas delivery system (such as the gas delivery systems 120 shown in FIG. 1) as described below in more detail. For example, the gas box 244 houses various valves, couplings, gas supply lines, manifolds, MFCs, etc. configured to supply respective gases and gas mixtures to the process modules 240. The gas box 244 is sealed to prevent leaking of gases between an interior of the gas box 244 and the atmosphere.

The vapor supply system 200 according to the present disclosure supplies vapor to the process modules 240 via the gas box 244. For example, vapor supply lines 248 from the evaporator assembly 204 are routed through and enclosed within the gas box 244. In some examples, the vapor supply lines 248 are heated from the evaporator assembly 204 to the process modules 240 to prevent the vapor from condensing/converting into liquid within the vapor supply lines 248 prior to being supplied to the process modules 240. For example, the vapor supply lines 248 are heated using resistive heaters, a jacket or wrap heater, etc. responsive to control signals received from the controller 228. In some examples, the vapor may be supplied to the process modules 240 at a sufficiently low pressure such that at room temperature (e.g., 17-25 degrees Celsius) the material is still in vapor form. Accordingly, it may not be necessary to heat hardware components upstream of the MFCs in the gas box 244 (e.g., within or external to the gas box 244). Conversely, supply pressure downstream of the MFCs and the gas box 244 is sufficiently low that heating is not required to maintain the material in vapor form.

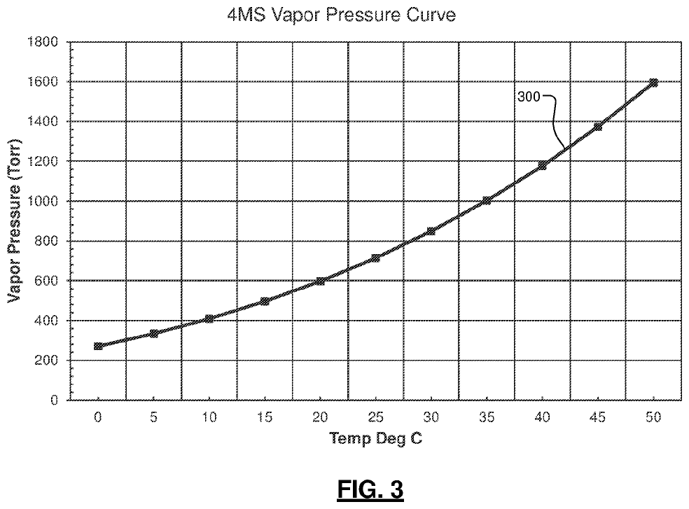

As one example, the vapor supply lines 248 are heated to maintain the temperature of the vapor below a vapor pressure curve 300 (e.g., a vapor pressure curve for 4MS) shown in FIG. 3. In other words, for a given pressure, the vapor supply lines 248 are heated to a temperature that is below the vapor pressure curve 300. For example, for a pressure of 1000 Torr, the vapor supply lines 248 are heated to ensure that the vapor is maintained at a temperature of at least 45 degrees Celsius. In some examples, the pressure is monitored by the controller 228 (e.g., using one more pressure sensors 252).

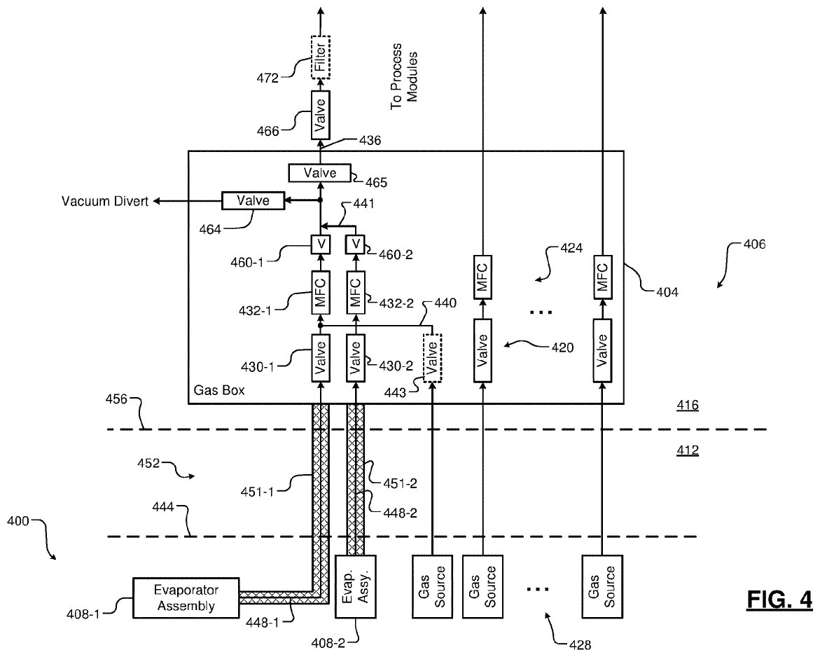

FIG. 4 illustrates an example configuration of a vapor supply system 400 according to the present disclosure in more detail. Note that FIG. 4 shows a general configuration that can supply only one vaporized precursor (e.g., 4MS) or can supply a mixture of two vaporized precursors (e.g., MoF6 and WF6). While elements 472 and 443 (described below) are used when supplying one vaporized precursor (e.g., 4MS), the elements 472 and 443 are not used and are omitted when supplying a mixture of two vaporized precursors (e.g., MoF6 and WF6). Therefore, the elements 472 and 443 are shown by dashed lines, which indicates that the elements 472 and 443 are present when supplying one vaporized precursor (e.g., 4MS) and are absent when supplying a mixture of two vaporized precursors (e.g., MoF6 and WF6).

As used herein, “vapor supply system” may refer to components associated with storage and supply of vapor external to and within the substrate processing tool 406, including a gas box 404 of a substrate processing tool 406. The vapor supply system 400 shown is configured to supply two vaporized precursors (e.g., MoF6 and WF6) via two branches. In applications where only one vaporized precursor is needed (e.g., 4MS), a second branch supplying a second vaporized precursor (e.g., elements 408-2, 448-2, 451-2, 430-2, 432-2, and 460-2) can be omitted. Note that 4MS, MoF6, and WF6 are used only as non-limiting examples of precursors. The principles of the present disclosure can be applied to any other precursor or combination of precursors.

In the vapor supply system 400 shown in FIG. 4, vapor comprising one or more vaporized precursors or reactants is supplied from one or more evaporator assemblies 408-1, 408-2, respectively. The vapor is routed through the gas box 404 to a process module (e.g., the processing chamber 112 shown in FIG. 1). For example, the vapor supply system 400 comprises a first evaporator assembly 408-1 and a second evaporator assembly 408-1 (collectively the evaporator assemblies 408). In applications where a mixture of two vaporized precursors (e.g., MoF6 and WF6) is used to process the substrate 118 in the processing chamber 112 (shown in FIG. 1), corresponding liquid precursors are heated and vaporized in respective evaporator assemblies 408-1, 408-1. In applications where only one vaporized precursor (e.g., 4MS) is used, the corresponding liquid precursor is heated and vaporized in the first evaporator assembly 408-1, and the second evaporator assembly 408-2 and subsequent elements connected to the second evaporator assembly 408-2 are omitted.

For example, the evaporator assemblies 408 are similar to the evaporator assembly 204 and/or the bulk liquid source 212 shown in FIGS. 2A and 2B. Depending on the precursor used, the evaporator assemblies 408 may heat respective liquid precursors to different temperatures to generate respective vaporized precursors. The evaporator assemblies 408 are located on a facilities side 412 in a facilities supply cabinet, below a floor of a fabrication facility, etc. Conversely, the gas box 404 is located on a tool side 416. As shown in FIG. 4, components shown on the tool side 416 may be located within an interior of the substrate processing tool 406, mounted on the substrate processing tool 406, etc. Some components of the vapor supply system 400 (shown in more detail in FIGS. 2A and 2B) are omitted from FIG. 4 for simplicity.

The first evaporator assembly 408-1 is connected to the gas box 404 by a first vapor supply line (also called a first conduit) 448-1. The first evaporator assembly 408-1 vaporizes a first liquid precursor and supplies a first vaporized precursor to a first input the gas box 404 via the first conduit 448-1. For example, in applications that use only one precursor (e.g., 4MS), the first evaporator assembly 408-1 supplies the precursor in vapor form. In applications that use two precursors (e.g., MoF6 and WF6), the first evaporator assembly 408-1 supplies the first vaporized precursor (e.g., MoF6). A first heater 451-1 is disposed around the first conduit 448-1 from an output of the first evaporator assembly 408-1 to the first input of the gas box 404. The first heater 451-1 is controlled by the controller (e.g., the controllers 136, 228 shown in FIGS. 1, 2A, 2B) to maintain the first vaporized precursor in vapor form in the first conduit 448-1 between the output of the first evaporator assembly 408-1 and the first input of the gas box 404.

The second evaporator assembly 408-2 is connected to the gas box 404 by a second vapor supply line (also called a second conduit) 448-2. The second evaporator assembly 408-2 vaporizes a second liquid precursor and supplies a second vaporized precursor to a second input the gas box 404 via the first conduit 448-2. For example, in applications that use only one precursor (e.g., 4MS), the second evaporator assembly 408-2 and subsequent components connected to the second evaporator assembly 408-2 are omitted. In applications that use two precursors (e.g., MoF6 and WF6), the second evaporator assembly 408-2 supplies the second vaporized precursor (e.g., WF6). A second heater 451-2 is disposed around the second conduit 448-2 from an output of the second evaporator assembly 408-2 to the second input of the gas box 404. The second heater 451-2 is controlled by the controller (e.g., the controllers 136, 228 shown in FIGS. 1, 2A, 2B) to maintain the second vaporized precursor in vapor form in the second conduit 448-2 between the output of the second evaporator assembly 408-2 and the second input of the gas box 404. Depending on the precursors, the controller may heat respective heaters 451-1, 451-2 to different temperatures to maintain respective vaporized precursors in vapor form in the conduits 448-1, 448-2.

Further, when supplying only one vaporized precursor (e.g., 4MS), a filter 472 and a valve 443 are used as described below. However, when supplying a mixture of two precursors (e.g., MoF6 and WF6), the filter and the valve 443 are omitted, and the description of the filter and the valve 443 applies only when supplying only one vaporized precursor (e.g., 4MS). Further, in some examples, when supplying only one vaporized precursor (e.g., 4MS), the filter 472 and a valve connected in series with the filter 472 may be disposed in the corresponding evaporator assembly (e.g., 408-1) to filter contaminants from the vaporized precursor before the vaporized precursor is supplied to the corresponding conduit (e.g., 448-1).

The gas box 404 comprises components such as valves 420, MFCs 424, and other valves described below, and associated couplings, supply lines, and manifolds (not shown). The gas box 404 is configured to receive one or more vaporized precursors from respective evaporator assemblies 408 and to receive gases and gas mixtures from respective gas sources 428. The gas box 404 is configured to supply the vaporized precursors and the gases to the process modules of the substrate processing tool 406. In some embodiments, the gas box 404 can be mounted below, above, or adjacent to the process modules. The gases are supplied to the gas box 404 from respective gas sources 428, which may be located in a same or different facilities cabinet as the evaporator assembly 408, below the floor, etc. The valves 420, MFCs 424, and the other valves are controlled (e.g., using the controllers 136, 228 shown in FIGS. 1, 2A, 2B) to control flow of gases and gas mixtures to the process modules as described below in detail. For example, one or more vaporized precursors and the gas mixtures are supplied to a process module (e.g., the processing chamber 112 shown in FIG. 1) via valve inlet block such as the valve inlet block 132 shown in FIG. 1.

The gas box 404 according to the present disclosure further comprises valves 430-1, 430-2 configured to receive one or more vaporized precursors supplied by the evaporator assemblies 408-1, 408-2 via the conduits 448-1, 448-2, respectively. Accordingly, the valves 430-1, 430-2 can be called inlet valves 430 of the gas box 404. The input valves 430-1, 430-2 are connected to mass flow controllers (MFCs) 432-1, 432-2, respectively. The gas box 404 comprises additional valves described below. By controlling the valves as described below in further detail, the gas box 404 supplies a vaporized precursor (in case of a single precursor such as 4MS) or a mixture of two precursors (e.g., MoF6 and WF6) to a process module (e.g., via vapor supply line and/or manifold 436).

Although the evaporator assemblies 408 are remotely located relative to the substrate processing tool 406 and the gas box 404, the precursor (e.g., 4MS) or the mixture of precursors (e.g., MoF6 and WF6) supplied from the gas box 404 to the process module is in vapor form for an entirety of the supply path from the evaporator assemblies 408, through the gas box 404, to the process module. More specifically, the precursors are maintained in vapor form in all vapor supply lines (e.g., in conduits 448-1, 448-2, in the gas box 404, and in the manifold 436). In other words, the precursors are not converted from liquid to vapor within any of the vapor supply lines (e.g., in conduits 448-1, 448-2, in the gas box 404, and in the manifold 436).

When supplying only one vaporized precursor (e.g., 4MS), another gas or gas mixture (e.g., a purge gas, molecular nitrogen (N₂), an inert gas, etc.) is supplied from a gas source 428 via a valve 443 and is added to (i.e., mixed with) the vaporized precursor in the gas box 404 (e.g., between the valve 430-1 and the respective MFC 432-1 as shown at 440. When supplying a mixture of two precursors (e.g., MoF6 and WF6), the gas or gas mixture is not added any of the two precursors or to the mixture of the two precursors.

The gas box 404 is sealed to prevent leaking of the vaporized precursors and the gases between an interior of the gas box 404 and atmosphere. Further, removing the evaporator assemblies 408 and associated components from the tool side 416 increases space available to other components, simplifies routing of supply line, facilitates maintenance and servicing, etc.

An exterior interface (shown as a dashed line) 444 between the facilities side 412 and the tool side 416 may correspond to an exterior surface of the substrate processing tool 406, such as an exterior panel, an enclosure of the substrate processing tool 406, etc. In some examples, the exterior interface 444 corresponds to an exterior disconnect panel. The vapor supply lines 448-1, 448-2 from the evaporator assemblies 408 (and, in some examples, supply lines from the gas sources 428) are connected to the exterior interface 444 using a respective connector or disconnect. In other words, the vapor supply lines 448-1, 448-2 may be removably connected to and disconnected from the substrate processing tool 406 at the exterior interface 444.

In some examples, the vaporized precursors supplied from the evaporator assemblies 408 are received and distributed by a vapor supply manifold or assembly 452. In some examples, a vapor supply interface (shown as a dashed line) 456 is disposed between the vapor supply assembly 452 and the gas box 404. For example, the vapor supply interface 456 corresponds to a disconnect panel. Accordingly, vapor supply lines within the substrate processing tool 406 may be connected to and disconnected from the vapor supply assembly 452 at the vapor supply interface 456.

The gas box 404 additionally comprises valves 460-1, 460-2 coupled to the MFCs 432-1, 432-2, respectively. An output of the valve 460-2 is connected to an output of the valve 460-2 as shown at 441. When two precursors are used, the two precursors are mixed (combined) downstream from the valves 460-1, 460-2. The valves 460-1, 460-2 can be called outlet valves 460 of the gas box 404.

The gas box 404 further comprises a valve 465. An input of the valve 465 is connected to the outputs of the valves 460-1, 460-2. An output of the valve 465 is connected to the vapor supply line and/or manifold 436. The valve 465 supplies a single vaporized precursor (e.g., 4MS) (e.g., output from the outlet valve 460-1) or a mixture of the first and second precursors (e.g., MoF6 and WF6) (e.g., output from the combined output of the outlet valves 460-1, 460-2) from the gas box 404 to the process module via the vapor supply line and/or manifold 436. Accordingly, the valve 465 in the gas box 404 can be called a chamber valve 465 through which the vaporized precursor(s) is/are supplied to the process module (e.g., the processing chamber 112 shown in FIG. 1).

The gas box 404 further comprises a valve 464 that is coupled between and the junction of the outputs of the valves 460-1, 460-2 (or the output of the valve 460-1 in applications supplying a single precursor such as 4MS) and the input of the valve 465 and a vacuum divert path that is connected to a foreline (exhaust system) of the substrate processing tool 406. Specifically, an input of the valve 464 is connected to the outputs of the valves 460-1, 460-2 (or the output of the outlet valve 460-1 when supplying a single precursor such as 4MS) and to the input of the valve 465. An output of the valve 464 is connected to the foreline (exhaust system) of the substrate processing tool 406. Accordingly, the input of the valve 464 is connected to a point that is downstream from outputs of the valves 460-1, 460-2 and that is upstream from the input of the valve 465. The valve 464 can be called a divert valve since the valve 464 is used to divert the vaporized precursor(s) to the foreline.

A valve 466 outside the gas box 404 is connected to an output of the valve 465. An output of the valve 465 is connected to an input of a filter 472. The filter 472 is used only when supplying only one precursor (e.g., 4MS). When supplying a mixture of two precursors (e.g., MoF6 and WF6), the filter 472 is not used. Instead, when supplying a mixture of two precursors (e.g., MoF6 and WF6), the output of the valve 465 is connected directly to a valve 466 outside the gas box 404 between the gas box 404 and the process module. When supplying only one precursor (e.g., 4MS), an output of the filter 472 is connected via the valve 466 to the process module (e.g., to the valve inlet block 132 of the processing chamber 112 shown in FIG. 1). That is, whether the filter 472 is used or not, the valve 466 is downstream from the valve 465 and upstream from the process module. The filter 472 is configured to filter particles from the vaporized precursor supplied from the gas box 404. The filter 472 prevents particle contamination from being introduced into the process module.

When a single precursor such as 4MS is used, elements 408-2, 451-2, valve 430-2, MFC 432-2, and valve 460-2 are omitted. The vaporized precursor (e.g., 4MS) is vaporized in the first vaporizer assembly 408-1 and the first vaporized precursor is supplied through the heated conduit 448-1, the valve 430-1, the MFC 432-1, the valve 460-1, the valve 465, the valve 466, and the filter 472 to the process module (e.g., the processing chamber 112 shown in FIG. 1). A non-reactive gas such as an inert gas (e.g., N2) is also supplied from one of the gas sources 428 through the valve 443 and is added to the first vaporized precursor between the valve 430-1 and the MFC 43-1 as shown.

When two precursors (e.g., MoF6 and WF6) are used, the first vaporized precursor (e.g., MoF6) is vaporized in the first vaporizer assembly 408-1 and the first vaporized precursor is supplied through the heated conduit 448-1, the valve 430-1, the MFC 432-1, the valve 460-1. Additionally, the second vaporized precursor (e.g., WF6) is vaporized in the second vaporizer assembly 408-2 and the second vaporized precursor is supplied through the heated conduit 448-2, the valve 430-2, the MFC 432-2, the valve 460-2. The first and second vaporized precursors are mixed at the outputs of the valves 460-1, 460-2. The first and second vaporized precursors are combined (i.e., mixed) at the outputs of the valves 460-1, 460-2 upstream of the valves 464 and 465. The mixture of the two vaporized precursors is supplied through the valve 465, and the valve 466 to the process module (e.g., the processing chamber 112 shown in FIG. 1). A non-reactive gas such as an inert gas (e.g., N2) is not supplied from one of the gas sources 428 through the valve 443 and is not added to the first and second vaporized precursors between the valves 430-1, 430-2 and the MFCs 43-1, 432-2.

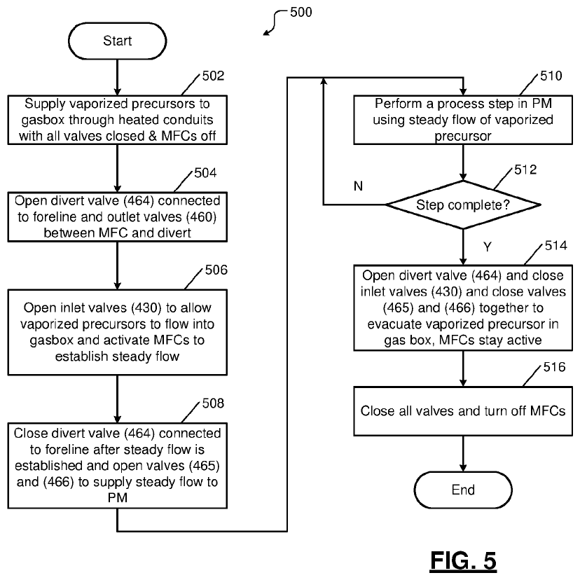

The operations of the valves 430-1, 430-2, the MFCs 432-1, 432-2, the valves 460-1, 460-2, and the valves 464, 465, 466 are described below in detail with reference to FIG. 5. Briefly, the valves 430-1, 430-2 (i.e., the inlet valves 430 of the gas box 404) are controlled to control supply of the first and second vaporized precursors to the MFCs 432-1, 432-2, respectively. The valves 460-1, 460-2 (i.e., the outlet valves 460 of the gas box 404) are controlled to control the mixing of the first and second vaporized precursors and to supply the mixture of the first and second vaporized precursors to the valves 464, 465. When only one precursor (e.g., 4MS) is used, the valve 460-1 (i.e., the outlet valve 460-1 of the gas box 404) is controlled to supply the vaporized precursor to the valves 464, 465. The valve 464 (i.e., the divert valve 464) is controlled in combination with other valves to control evacuation of the one or more vaporized precursors from the gas box 404 as described below in detail. The valve 465 (i.e., the chamber valve 465) is controlled to control the supply of a single vaporized precursor (e.g., 4MS) or a mixture of precursors (e.g., MoF5 and WF6) to the valve 466. The valve 466 is controlled to control the supply of the vaporized precursor (e.g., 4MS) or a mixture of the vaporized precursors (e.g., MoF5 and WF6) to the process module via the filter 472.

When a vaporized precursor (e.g., 4MS) or a mixture of vaporized precursors (e.g., MoF6 and WF6) is supplied to the process module, the vaporized precursor (or the mixture) must flow in steady state into the process module and must flow in vapor form into the process module for processing a substrate. Further during a process step and between successive process steps, the vaporized precursor (or the mixture) must not condense in any of the supply lines (conduits) and valves anywhere from the vaporizer assemblies 408 to the process module.

The vaporized precursor (or the mixture) can be maintained in vapor form between the vaporizer assemblies 408 and the gas box 404 by heating the conduits 448-1, 448-2. However, the gas box 404 is generally at room temperature (and typically also at atmospheric pressure) while the evaporator modules 408 are at a higher temperature than the gas box 404. Accordingly, if the vaporized precursor (or the mixture) remains in the conduits in the gas box 404 when not supplied to the process module (e.g., between two process steps), the vaporized precursor (or the mixture) can condense in the conduits and valves in the gas box 404 due to the difference between temperatures of the evaporator modules 408 and the gas box 404. Further, coflowing the two vaporized precursors increases the pressure at the input of the gas box 404 while the gas box 404 is typically at atmospheric pressure, which further exacerbates the risk of condensation of the vaporized precursors in the gas box 404 since the temperatures of the evaporator modules 408 is greater than that of the gas box 404.

Therefore, when the vaporized precursor (or the mixture) is not supplied to the process module (e.g., between two process steps), the controller (136 or 228) controls the various valves as described below with reference to FIG. 5 to evacuate the vaporized precursor (or the mixture) from the gas box 404 by diverting the vaporized precursor (or the mixture) to the foreline via the divert valve 464. Note that during substrate processing, there is no risk of condensation downstream of the valve 465 due to a drop in pressure across the MFCs 432 and low pressure generally from the gas box 404 to the process module,

Further, before supplying the vaporized precursor (or the mixture) to the process module, the controller (136 or 228) controls the various valves as described below with reference to FIG. 5 to first establish a steady state flow of the vaporized precursor (or the mixture) and then supplies the steady flow of the vaporized precursor (or the mixture) to the process module. The process of evacuation follows each process step performed in the process module, and the process of establishing a steady flow precedes every process step performed in the process module. The steps of establishing steady state flow and evacuation are repeated alternatingly and cyclically before and after each process step performed in the process module as described below in detail.

FIG. 5 shows a method 500 of supplying a single vaporized precursor (e.g., 4MS) or a mixture of two vaporized precursors (e.g., MoF6 and WF6) from the system shown in FIG. 4 to a process module (e.g., the processing chamber 112 shown in FIG. 1). For example, the method 500 may be performed by the controller 136 or 228.

The method 500 is described with reference to a mixture of two vaporized precursors (e.g., MoF6 and WF6). However, the method 500 applies equally to supplying a single vaporized precursor (e.g., 4MS). Specifically, the sequencing of the various valves described below for supplying a mixture of two vaporized precursors (e.g., MoF6 and WF6) is the same when supplying a single vaporized precursor (e.g., 4MS) except that instead of both inlet valves 430, MFCs 432, and outlet valves 460, only one inlet valve 430-1, one MFC 432-1, and one outlet valve 460-1 are controlled as described. All other valves are controlled in the same manner as described irrespective of whether a single vaporized precursor (e.g., 4MS) or a mixture of two vaporized precursors (e.g., MoF6 and WF6) is supplied to a process module. Therefore, while some of the elements are referred to as plurals to describe supplying a mixture of two vaporized precursors (e.g., MoF6 and WF6) to the process module, these elements, when read as singular, describe supplying a single vaporized precursor (e.g., 4MS) to the process module.

In the following description the inlet valves 430-1 and 430-2 are collectively called the inlet valves, the MFCs 432-1 and 432-2 are collectively called the MFCs 432, and the outlet valves 460-1 and 460-2 are collectively called the outlet valves 360. Again, while the inlet valves 430, the MFCs 43, and the outlet valves 460 are described as plurals when describing supplying a mixture of two vaporized precursors (e.g., MoF6 and WF6) to the process module, these elements, when read as singular, describe supplying a single vaporized precursor (e.g., 4MS) to the process module.

At 502, the controller closes all valves (inlet valves 430, outlet valves 460, the divert valve 464, the chamber valve 465, and the valve 466) and the MFCs 432-1, 432-1 (collectively called the MFCs 432) are off. The vaporizers assemblies 408 supply vaporized precursors to the gas box 404 via separate heated conduits 448-1, 448-2.

At 504, the controller opens the divert valve 464 connected to the foreline and opens the outlet valves 460 between the MFCs 432 and the divert valve 464. At 506, the controller opens the inlet valves 430 to allow the vaporized precursors to flow into the gas box 404. The controller activates (turns on and sets the flow rate set points of) the MFCs 432.

When supplying only one precursor (e.g., 4MS), the controller also activates the valve 443 to add a gas or a gas mixture (e.g., N2) to each of the vaporized precursor (e.g., 4MS). The vaporized precursor and the added gas or gas mixture combine at the outputs of the outlet valve 460-1 to form a mixture of the vaporized precursor and the added gas or gas mixture. The mixture of the vaporized precursor and the added gas or gas mixture flows through the divert valve 464 until a steady state flow of the mixture of the vaporized precursor and the added gas or gas mixture is established.

When supplying a mixture of two precursors (e.g., MoF6 and WF6), a gas or a gas mixture (e.g., N2) is not added to any of the two precursors or their mixture. If the valve 443 is present, the controller does not activate the valve 443 to add a gas or a gas mixture (e.g., N2) to any of the two precursors or their mixture. The two vaporized precursors combine at the outputs of the outlet valve 460-1 to form a mixture of the two vaporized precursors. The mixture of the two vaporized precursors flows through the divert valve 464 until a steady state flow of the mixture of the two vaporized precursors is established. Hereinafter, the mixture of the two vaporized precursors in case as well as the mixture of the vaporized precursor and the added gas or gas mixture are both called “the mixture.”

At 508, the controller closes the divert valve 464 connected to the foreline after the steady state flow of the mixture is established. The controller opens the valves 465 and 466 to supply the steady state flow of the mixture to the process module. At 510, a process step of a process recipe is performed on the substrate in the process module using the steady state flow of the mixture.

At 512, the controller determines if the process step is completed. If the process step is not completed, step 510 is continued. If the process step is completed, at 514, the controller opens the divert valve 464, closes the inlet valves 430, and closes the valves 465 and 466 together, while keeping the outlet valves 460 open and the MFCs 432 on, to evacuate the mixture from the gas box 404 through the foreline to prevent condensation of the vaporized precursors or the vaporized precursor in the gas box 404. At 516, the controller closes all the valves. To perform a next process step of the process recipe or a process step of another process recipe, the steps 504-516 are repeated.

Note that when using two precursors (e.g., MoF6 and WF6), heating both conduits 448-1 and 448-2 may be optional depending on the boiling points of the liquid precursors. For example, the boiling point of MoF6 at standard atmospheric pressure is greater than room temperature while WF6 boils below room temperature. Therefore, while the conduit (e.g., 448-1) supplying MoF6 may be heated, the conduit (e.g., 448-2) supplying WF6 need not be heated. Further, when MoF6 and WF6 are used, the evacuation step described above is intended to prevent condensation of MoF6.

Further, when using a single precursor (e.g., 4MS), the vapor pressure of 4MS is higher than that of MoF6. Therefore, the evacuation step can be optional when using a single precursor (e.g., 4MS). Thus, the heating of conduits and the evacuation step depend on individual chemical and thermodynamic properties of the precursor or precursors used.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system for supplying vaporized precursors to a process module of a substrate processing tool comprising:
a first evaporator assembly configured to vaporize a first liquid precursor and to supply a first vaporized precursor through a first conduit;
a second evaporator assembly configured to vaporize a second liquid precursor and to supply a second vaporized precursor through a second conduit; and
a gas box configured to mix the first and second vaporized precursors, to supply a mixture of the first and second vaporized precursors to the process module, and to at least partially evacuate the mixture from the gas box after a process step is completed to prevent condensation of at least one of the first and second vaporized precursors in the gas box.

2. The system of claim 1 wherein the gas box is further configured to establish a steady flow of the mixture of the first and second vaporized precursors before supplying the mixture to the process module.

3. The system of claim 1 wherein at least one of the first and second conduits is heated to supply the first and second vaporized precursors to the gas box in vapor form.

4. The system of claim 1 wherein the gas box is connected to an exhaust system to evacuate the mixture.

5. The system of claim 1 wherein the gas box is further configured to receive a gas from a gas source and to add the gas to at least one of the first and second vaporized precursors before mixing the first and second vaporized precursors.

6. The system of claim 1 wherein the gas box comprises:
a first inlet valve to receive the first vaporized precursor from the first evaporator assembly via the first conduit;
a second inlet valve to receive the second vaporized precursor from the second evaporator assembly via the second conduit;
a first mass flow controller connected to the first inlet valve to regulate flow of the first vaporized precursor;
a second mass flow controller connected to the second inlet valve to regulate flow of the second vaporized precursor;
a first outlet valve connected to the first mass flow controller;
a second outlet valve connected to the second mass flow controller;
a first valve having an input connected to outputs of the first and second outlet valves and having an output connected to a second valve coupled to the process module; and
a third valve connected between input of the first valve and the outputs of the first and second outlet valves.

7. The system of claim 6 further comprising a controller configured to, before supplying the mixture to the process module:
close the first and second inlet valves, the first and second outlet valves, the first and second valves, and turn off the first and second mass flow controllers;
open the third valve and the first and second outlet valves;
open the first and second inlet valves o allow the first and second vaporized precursors to flow through the first and second conduits into the gas box;
turn on the first and second mass flow controllers to allow flow of the mixture to reach a steady state; and
after the flow of the mixture reaching the steady state, close the third valve and open the first and second valves to supply the mixture to the process module.

8. The system of claim 7 wherein the controller is further configured to, after the process step is performed in the process module using the mixture:
open the third valve;
close the first and second inlet valves and the first and second valves, while keeping the first and second outlet valves open and the first and second mass flow controllers on, to evacuate the mixture from the gas box and to prevent condensation of at least one of the first and second vaporized precursors in the gas box;
close the first and second inlet valves, the first and second outlet valves, the first and second valves; and
turn off the first and second mass flow controllers.

9. The system of claim 1 further comprising:
a first heater coupled to the first conduit;
a second heater coupled to the second conduit; and
a controller configured to control the first and second heaters to heat the first and second conduits to first and second temperatures, respectively, to maintain the first and second vaporized precursors in the first and second conduits in vapor form.

10. The system of claim 1 further comprising:
a first heater coupled to the first evaporator assembly;
a second heater coupled to the second evaporator assembly; and
a controller configured to control the first and second heaters to heat the first and second liquid precursors to first and second temperatures, respectively, to vaporize the first and second liquid precursors into the first and second vaporized precursors.

11. The system of claim 1 wherein the first and second liquid precursors comprise molybdenum hexafluoride and tungsten hexafluoride, respectively.

12. The system of claim 1 wherein the first and second evaporator assemblies are located in a facilities supply cabinet external to the substrate processing tool and wherein the gas box is mounted on or within the substrate processing tool.

13. The system of claim 1 wherein the first and second evaporator assemblies are located below a floor of a facility containing the substrate processing tool and wherein the gas box is mounted on or within the substrate processing tool.

14. A system for supplying a vaporized precursor to a process module of a substrate processing tool comprising:
an evaporator assembly configured to vaporize a liquid precursor and to supply the vaporized precursor through a conduit; and
a gas box configured to supply the vaporized precursor to the process module and to at least partially evacuate the vaporized precursor from the gas box after a process step is completed to prevent condensation of vaporized precursor in the gas box.

15. The system of claim 14 wherein the gas box is further configured to establish a steady flow of the vaporized precursor before supplying the vaporized precursor to the process module.

16. The system of claim 14 wherein the conduit is heated to supply the vaporized precursor to the gas box in vapor form.

17. The system of claim 14 wherein the gas box is connected to an exhaust system to evacuate the vaporized precursor.

18. The system of claim 14 wherein the gas box is further configured to receive a gas from a gas source and to add the gas to the vaporized precursor.

19. The system of claim 14 wherein the gas box comprises:
an inlet valve to receive the vaporized precursor from the evaporator assembly via the conduit;
a mass flow controller connected to the inlet valve to regulate flow of the vaporized precursor;
an outlet valve connected to the mass flow controller;
a first valve having an input connected to an output of the outlet valve and having an output connected to a second valve coupled to the process module; and
a third valve connected between input of the first valve and the output of the outlet valve.

20. The system of claim 19 further comprising a controller configured to, before supplying the vaporized precursor to the process module:
close the inlet and outlet valves, the first and second valves, and turn off the mass flow controller;
open the third valve and the outlet valve;
open the inlet valve to allow the vaporized precursor to flow through the conduit into the gas box;
turn on the mass flow controller to allow flow of the vaporized precursor to reach a steady state; and
after the flow of the vaporized precursor reaching the steady state, close the third valve and open the first and second valves to supply the vaporized precursor to the process module.

21. The system of claim 20 wherein the controller is further configured to, after the process step is performed in the process module using the vaporized precursor:
open the third valve;
close the inlet valve and the first and second valves, while keeping the outlet valve open and the mass flow controller on, to evacuate the vaporized precursor from the gas box and to prevent condensation of the vaporized precursor in the gas box; and
close the inlet and outlet valves and the first and second valves, and turn off the mass flow controller.

22. The system of claim 14 further comprising:
a heater coupled to the conduit; and
a controller configured to control the heater to heat the conduit to maintain the vaporized precursor in the conduit in vapor form.

23. The system of claim 14 further comprising:
a heater coupled to the evaporator assembly; and
a controller configured to control the heater to heat the liquid precursor to vaporize the liquid precursor into the vaporized precursor.

24. The system of claim 19 wherein the gas box further comprises a fourth valve connected to a source of an inert gas, the fourth valve being connected between the inlet valve and the mass flow controller to add the inert gas to the vaporized precursor.

25. The system of claim 14 wherein the liquid precursor comprises tetramethylsilane.

26. The system of claim 19 further comprising a filter connected between the second valve and the process module to filter contaminants from the vaporized precursor supplied to the process module.

27. The system of claim 14 wherein the evaporator assembly is located in a facilities supply cabinet external to the substrate processing tool and wherein the gas box is mounted on or within the substrate processing tool.

28. The system of claim 14 wherein the evaporator assembly is located below a floor of a facility containing the substrate processing tool and wherein the gas box is mounted on or within the substrate processing tool.
